(19) United States
(12) Patent Application Publication
(10) Pub. No.: US 2025/0353967 A1
(43) Pub. Date: Nov. 20, 2025

(54) CURABLE SILOXANE RESIN COMPOSITION AND FILM INCLUDING THE SAME

(71) Applicant: Korea Advanced Institute of Science and Technology, Daejeon (KR)

(72) Inventors: Byeong-Soo BAE, Daejeon (KR); Jaekyeong LEE, Daejeon (KR); Seung-Mo KANG, Daejeon (KR)

(73) Assignee: Korea Advanced Institute of Science and Technology, Daejeon (KR)

(21) Appl. No.: 19/005,102

(22) Filed: Dec. 30, 2024

(30) Foreign Application Priority Data
May 16, 2024 (KR) 10-2024-0063788

(51) Int. Cl. C08G 77/20; B32B 5/02; B32B 15/14; B32B 15/20; C08G 77/00; C08G 77/18; C08J 5/18; C08J 5/24; H05K 1/03

(52) U.S. Cl. CPC C08G 77/20; B32B 5/02; B32B 15/14; B32B 15/20; C08G 77/18; C08J 5/18; C08J 5/243; B32B 2260/021; B32B 2260/046; B32B 2262/101; B32B 2307/204; B32B 2307/30; B32B 2307/308; B32B 2307/726; B32B 2457/08; C08G 77/80; C08J 2383/07; H05K 1/0373

(57) ABSTRACT

A curable siloxane resin composition includes a siloxane resin and a radical initiator. The siloxane resin is obtained through a hydrolytic condensation reaction of a mixture of a trialkoxysilane having an alkenyl group and a dialkoxysilane having at least one aryl group. Thus, the curable siloxane resin composition may form a cured material having suitable characteristics for low dielectric insulation materials of ultra-high frequency/ultra-high speed electronic devices.

### CROSS-REFERENCE TO RELATED APPLICATION

This application claims priority to and benefits of Korean Patent Application No. 10-2024-0063788 under 35 U.S.C. § 119 filed on May 16, 2024 in the Korean Intellectual Property Office, the entire contents of which are incorporated herein by reference.

### BACKGROUND

### 1. Technical Field

The present invention relates to a siloxane resin composition and a film, which have characteristics suitable for a material for a low-dielectric insulation layer of ultra-high frequency/ultra-high speed electronic devices.

### 2. Description of the Related Art

Ultra-high frequency/ultra-high speed electronic devices, which may be necessary for industries such as 5G/6G communications, virtual reality (VR), artificial intelligence (AI), self-driving cars, high-performance computing (HPC) or the like, are capable of rapidly transmitting, receiving, and processing large amounts of data, and can establish hyper-connections between large amounts of devices. Thus, their market size is growing rapidly. The ultra-high frequency/ultra-high speed electronic devices may operate in frequency bands of gigahertz (GHz) or higher. In order to maintain performance of electronic devices in frequency bands of gigahertz or higher, transmission loss occurring in internal circuits, which includes printed circuit boards, integrated circuits and semiconductor packaging redistribution layers (RDLs), needs to be minimized. Thus, various research and development are being conducted to reduce circuit transmission loss in ultra-high frequency/ultra-high speed electronic devices.

Transmission loss may be expressed as the sum of conductor loss and dielectric loss. In high frequency bands, dielectric loss accounts for a very large portion. Since the dielectric loss is determined by dielectric constant and dielectric loss tangent of an insulation layer that forms a circuit, materials having low dielectric constant and dielectric loss tangent may be used for insulation materials in order to minimize transmission loss of ultra-high frequency/ultra-high speed electronic devices.

Many materials have been suggested for insulation materials for the ultra-high frequency/ultra-high speed electronic devices so far. However, since it is difficult for the materials to simultaneously satisfy suitable thermal, mechanical and dielectric reliabilities, the materials have limitations for practical application. For example, the polyimide resin composition suggested in PCT Publication No. 2022-163335 does not have sufficient dielectric characteristics. The polyphenylene resin composition suggested in U.S. Patent Publication No. 2023-0312912 has a low glass-transition temperature so that thermal reliability thereof is low. Even though the liquid crystal resin containing a filler suggested in U.S. Granted U.S. Pat. No. 11,760,932 has superior dielectric characteristics, reliability at a via hole is low due to anisotropy of chemical structures of liquid crystal resin. Furthermore, the methacrylic resin suggested in U.S. Patent Publication No. 2022-0169769 was not evaluated by a general method for measuring dielectric characteristics. The bismaleimide resin suggested in U.S. Granted U.S. Pat. No. 11,678,432 has not clearly showed experimental results about its thermo-mechanical reliability such as a glass-transition temperature. The epoxy resin composition suggested in Japanese Granted U.S. Pat. No. 6,867,459 has not clearly showed experimental results about its dielectric constant and reliability. Thus, it is difficult to determine that the above-suggested materials are suitable for insulation materials of ultra-high frequency/ultra-high speed electronic devices.

Korean Patent Publication No. 2023-0039848 has suggested a siloxane resin having a low dielectric constant and dielectric loss tangent in high frequency bands, a low water absorption and a superior thermo-mechanical reliability, which has showed possibility for insulation materials of ultra-high frequency/ultra-high speed electronic devices. However, since the siloxane resin has fluidity due to a high ratio of loss modulus and storage modulus at room temperature, it is difficult to form a free-standing film. Thus, it is difficult to apply the siloxane resin for a process of depositing insulation materials to form high-integrated circuits. Furthermore, since precursors of the siloxane resin cost high, cost competitiveness may be low. Thus, research and developments are necessary for a novel resin having superior thermo-mechanical characteristics and reliability, possibility for forming a free-standing film and cost competitiveness as well as a low dielectric constant and a low dielectric loss tangent in frequency bands of gigahertz or higher.

### SUMMARY

One object of the present invention is to provide a curable siloxane resin composition, which has suitable characteristics for insulation materials of ultra-high frequency/ultra-high speed electronic devices, such as a low dielectric constant and dielectric loss tangent, a low water absorption, a high glass-transition temperature, a low thermal expansion (coefficient of thermal expansion), a low ratio of loss modulus and storage modulus, cost competitiveness or the like.

According to an embodiment of the present invention, a curable siloxane resin composition includes a siloxane resin and a radical initiator. The siloxane resin is obtained through a hydrolytic condensation reaction of a mixture of a trialkoxysilane having an alkenyl group and a dialkoxysilane having at least one aryl group. The siloxane resin is represented by the following Chemical Formula 1,

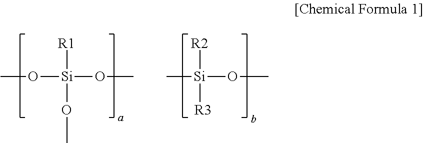

In Chemical Formula 1, R1 includes a linear or branched C₂₋₂₀ alkenyl group, R2 includes a linear or branched C₆₋₂₀ aryl group, R3 includes a linear or branched C₆₋₂₀ aryl group, a C₁₋₂₀ alkyl group or a C₂-20 alkenyl group, a and b are natural numbers, and b is larger than or equal to a.

In an embodiment, the number average molecular weight of the siloxane resin is 1,000 g/mol to 15,000 g/mol, and the weight average molecular weight of the siloxane resin is 1,000 g/mol to 30,000 g/mol.

In an embodiment, the trialkoxysilane includes at least one of the group consisting of vinyltrimethoxysilane, vinyltriethoxysilane, allyltrimethoxysilane, allyltriethoxysilane, trimethoxy (4-vinylphenyl) silane and triethoxy (4-vinylphenyl) silane.

In an embodiment, the dialkoxysilane includes at least one of the group consisting of methylphenyldimethoxysilane, methylphenyldiethoxysilane, diphenyldimethoxysilane, diphenyldiethoxysilane, 1,4-bis(methoxydimethylsilyl)benzene, 1,4-bis(ethoxydimethylsilyl)benzene, 4-vinyldiphenyldimethoxysilane and 4-vinyldiphenyldiethoxysilane.

In an embodiment, the radical initiator includes at least one of the group consisting of 2,3-dimethyl-2,3-diphenylbutane, 2,5-dimethyl-2,5-di(tert-butylperoxy)hexyne-3, 3,6,9-triethyl-3,6,9-trimethyl-1,4,7-triperoxonane, di(tert-butyl)-peroxide, 2,5-dimethyl-2,5-di(tert-butylperoxy)hexane, di(tert-butylperoxy-isopropyl)benzene, tert-butylcumylperoxide, di-(tert-amyl)-peroxide, dicumylperoxide, butyl4,4-di(tert-butylperoxy)valerate, tert-butylperoxybenzoate, 2,2-di(tert-butylperoxy)butane, tert-amylperoxy-benzoate, tert-butylperoxy-acetate, tert-butylperoxy-(2-ethyl hexyl)carbonate, tert-butylperoxy isopropyl carbonate, tert-butylperoxy-3,5,5-trimethyl-hexanoate, 1,1-di(tert-butylperoxy)cyclohexane, tert-amylperoxyacetate, tert-amylperoxy-(2-ethylhexyl)carbonate, 1,1-di(tert-butylperoxy)-3,5,5-trimethylcyclohexane, 1,1-di(tert-amylpooxy)cyclohexane, tert-butyl-monoperoxy-malate, 1,1′-azodi(hexahydrobenzonitrile), tert-butylperoxy-isobutyrate, tert-butyl peroxydiethylacetate, tert-butylperoxy-2-ethyl hexanoate, benzoyl peroxide, tert-amylperoxy-2-ethylhexanoate, di(3-methylbenzoyl)peroxide, 1,1,3,3-tetramethylbutyl peroxy-2-ethylhexanoate, ammonium peroxodisulfate, 2,5-dimethyl-2,5-di(2-ethylhexanoylperoxy)hexane, 2,2′-azodi(2-methylbutyronitrile), 2,2′-azodi(isobutyronitrile), didecanoylperoxide, dilauroylperoxide, di(3,5,5-trimethylhexanoyl)peroxide, tert-amylperoxypivalrate, tert-butylperoxyneoheptanoate, 1,1,3,3-tetramethylbutyl peroxypivalate, tert-butylperoxypivalate, dicetylperoxydicarbonate, dimyristyl peroxydicarbonate, di(2-ethylhexyl)peroxydicarbonate, di(4-tert-butylcyclohexyl) peroxycarbonate, diisopropylperoxydicarbonate, tert-butylperoxyneodecanoate, di-sec-butylperoxydicarbonate, tert-amylperoxyneodecanoate, cumyl peroxyneoheptanoate, di(3-methoxybutyl) peroxydicarbonate, 1,1,3,3-tetramethyl butylperoxyneodecanoate, cumylperoxyneodecanoate, diisobutyrylperoxide,bBenzoin, benzoin ethylether, phenylbis(2,4,6-trimethylbenzoyl) phosphine oxide, 1-hydroxycyclohexylphenyl ketone, 2,2-dimethoxy-2-phenylacetophenone, and an oxime ester compound.

In an embodiment, a ratio of loss modulus and storage modulus of the curable siloxane resin composition is 1 or less.

According to an embodiment of the present invention, a film includes a cured material of the curable siloxane resin composition.

In an embodiment, the cured material has a dielectric constant of 3.3 or less and a dielectric loss tangent of 0.003 or less at a frequency of 10 GHz.

According to an embodiment of the present invention, a composite film includes a cured material of the curable siloxane resin composition and at least one of a glass cloth and an inorganic filler.

According to an embodiment of the present invention, a copper clad laminate includes the composite film.

According to embodiments of the present invention, a cured material of a curable siloxane resin composition may have a low dielectric constant and dielectric loss tangent, a low water absorption, a high glass-transition temperature, a low thermal expansion, cost competitiveness or the like. Thus, the cure material may have suitable characteristics for insulation materials of ultra-high frequency/ultra-high speed electronic devices.

Furthermore, since the curable siloxane resin composition may have a large storage modulus at a room temperature, the ratio of loss modulus and storage modulus is small. Thus, the curable siloxane resin composition may behavior like solid, which is not sticky, without an additional curing process thereby forming a film, a sheet and a role, which can be easily handled. Thus, the curable siloxane resin composition may provide great convenience for manufacturing processes for forming a low dielectric insulation layer of ultra-high frequency/ultra-high speed electronic devices.

### DETAILED DESCRIPTION OF THE EMBODIMENTS

An exemplary embodiment of the present invention will be described in detail so that a person of an ordinary skill in the art to which the present invention pertains may easily implement the same. As those skilled in the art would realize, the described embodiments may be modified in various different ways, all without departing from the spirit or scope of the present invention. In addition, in the case of a well-known technology, a detailed description thereof will be omitted.

Throughout the specification, unless explicitly described to the contrary, the terms “comprise” and “include”, and variations such as “comprises” “comprising” “includes” or “including”, will be understood to imply the inclusion of stated elements but not the exclusion of any other elements.

Throughout the specification, the terms “about” and “substantially” are used in the sense of at, or nearly at, when given the manufacturing and material tolerances inherent in the stated circumstances and are used to prevent the unscrupulous infringer from unfairly taking advantage of the present disclosure where exact or absolute numerical values are disclosed as an aid to understanding the present disclosure.

Throughout the specification, the terms “step” or “step of” are not limited to mean “step for”.

Throughout the specification, it will be understood that when an element or layer is referred to as being “on,” “connected to” or “coupled to” another element or layer, it can be directly on, connected or coupled to the other element or layer or intervening elements or layers such as for electrical connection may be present.

Throughout the specification, when an element is referred to as being “directly on,” “directly connected to” or “directly coupled to” another element or layer, there are no intervening elements or layers present.

Throughout the specification, the term “combination(s) thereof” included in an expression of the Markush form will be understood to imply mixing or combination of at least one selected from the group consisting of the constituent elements described in the expression of the Markush form, referring to the inclusion of at least one selected from the group consisting of constituent elements.

Throughout the specification, the term “alkyl group” used herein may include a linear or branched C₁₋₇ alkyl group or a C₁₋₂₀ alkyl group, respectively, for example, methyl, ethyl, propyl, butyl, pentyl, hexyl, heptyl, octyl, nonyl, decyl, undecyl, dodecyl, tridecyl, tetradecyl, pentadecyl, hexadecyl, heptadecyl, octadecyl, nonadecyl, eicosanyl, or all possible isomers thereof, however, may not be limited thereto.

Throughout the specification, the term “alkenyl group” used herein refers to a monovalent hydrocarbon group in which at least one carbon-carbon double bond is included in an alkyl group having two or more carbon atoms in the alkyl groups and may be the inclusion of a linear or branched, C₂₋₂₀ alkenyl group, however, may not be limited thereto.

Throughout the specification, the term “an aryl group” used herein refers to a monovalent functional group formed by removal of a hydrogen atom present in at least one cyclic arene and may include a C₆₋₂₀ aryl group, for example, phenyl, biphenyl, terphenyl, naphthyl, anthryl, phenanthryl, pyrenyl, or all possible isomers thereof, however, may not be limited thereto. Arene is a hydrocarbon group having an aromatic cyclic ring and includes a monocyclic or polycyclic hydrocarbon group, and the polycyclic hydrocarbon group may include at least one aromatic cyclic ring and may include an aromatic cyclic or a non-aromatic cyclic ring as an additional cyclic ring, however, may not be limited thereto.

Throughout the specification, the term “alkoxy group or alkoxy” used herein refers to a form to which an alkyl group and an oxygen atom are bonded and may include a C₁₋₂₀ alkoxy group, for example, methoxy, ethoxy, propoxy, butoxy, pentoxy, hexyloxy, heptyloxy, octyloxy, nonyloxy, decyloxy, undecyloxy, dodecyloxy, tridecyloxy, tetradecyloxy, pentadecyloxy, hexadecyloxy, heptadecyloxy, octadecyloxy, nonadecyloxy, eicosanyloxy, or all possible isomers thereof,, however, may not be limited thereto.

Throughout the specification, the term “curable siloxane resin composition” used herein refers to a composition including a curable siloxane resin, and/or a radical initiator for curing of a siloxane resin.

Hereinafter, a method for manufacturing a curable siloxane resin composition according to an embodiment of the present invention will be described more fully.

A curable siloxane resin composition according to an embodiment includes a siloxane resin and a radical initiator. The siloxane resin is obtained through a hydrolytic condensation reaction of a mixture of a trialkoxysilane having an alkenyl group, a dialkoxysilane having at least one aryl group and a catalyst, which includes an acid or base aqueous solution, and is represented by the following Chemical Formula 1.

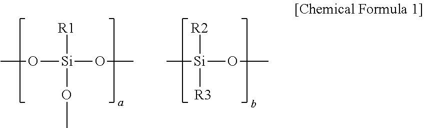

In Chemical Formula 1, R1 includes a linear or branched C₂₋₂₀ alkenyl group, R2 includes a linear or branched C₆₋₂₀ aryl group, R3 includes a linear or branched C₆₋₂₀ aryl group, a C₁₋₂₀ alkyl group or a C₂₋₂₀ alkenyl group, a and b are natural numbers, and b is larger than or equal to a.

The oxygen atom may form a first bond with a silicon atom, and may form a second bond with a silicon atom or another connecting group (e.g., a C₆₋₂₀ arylene group or a C₁₋₅ alkylene group).

For example, the number average molecular weight of the compound of the above Chemical Formula 1 may be from 1,000 g/mol to 15,000 g/mol, and the weight average molecular weight may be from 1,000 g/mol to 30,000 g/mol. In the present application, the molecular weight is calculated or measured by GPC analysis (based on polystyrene).

The trialkoxysilane including the alkenyl group may include at least one of the compounds represented by the following Chemical Formula 2-1.

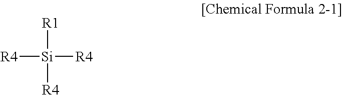

In Chemical Formula 2-1, R1 includes a linear or branched C₂₋₂₀ alkenyl group, and R4 includes a C₁₋₅ alkoxyl group.

The dialkoxysilane including at least one aryl group may include at least one of the compounds represented by the following Chemical Formulas 3-1 and 3-2.

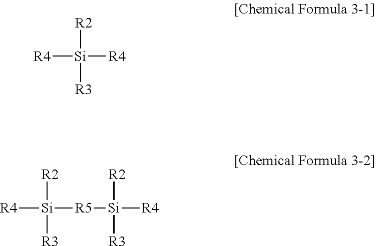

In Chemical Formulas 3-1 and 3-2, R2 includes a linear or branched C₆₋₂₀ aryl group, R3 includes a linear or branched C₆₋₂₀ aryl group, a C₁₋₂₀ alkyl group or a C₂₋₂₀ alkenyl group, R4 includes a C₁₋₅ alkoxyl group, and R5 includes a C₆₋₂₀ arylene group or a C₁₋₅ alkylene group.

For example, the trialkoxysilane including the alkenyl group may include vinyltrimethoxysilane, vinyltriethoxysilane, allyltrimethoxysilane, allyltriethoxysilane, trimethoxy(4-vinylphenyl)silane, triethoxy(4-vinylphenyl)silane or a combination thereof.

For example, the dialkoxysilane including at least one aryl group may include methylphenyldimethoxysilane, methylphenyldiethoxysilane, diphenyldimethoxysilane, diphenyldiethoxysilane, 1,4-bis(methoxydimethylsilyl)benzene, 1,4-bis(ethoxydimethylsilyl)benzene, 4-vinyldiphenyldimethoxysilane, 4-vinyldiphenyldiethoxysilane or a combination thereof.

The siloxane resin obtained the from hydrolytic condensation reaction of the mixture of the trialkoxysilane having an alkenyl group, the dialkoxysilane having at least one aryl group and the catalyst is advantages for simultaneously having suitable characteristics for insulation materials of ultra-high frequency/ultra-high speed electronic devices, such as a low dielectric constant and dielectric loss tangent, a low water absorption, a high glass-transition temperature, a low thermal expansion, a low ratio of loss modulus and storage modulus or the like.

Particularly, the siloxane resin obtained from hydrolytic condensation reaction of the mixture of the trialkoxysilane having an alkenyl group, the dialkoxysilane having at least one aryl group and the catalyst may have a remarkably increased condensation degree of siloxane bonds and an increased rigidity of a molecular structure. Thus, the dielectric constant and the dielectric loss tangent of the cured material of the siloxane resin composition may be much increased, and the water absorption thereof may be much increased due to decrease of hydroxyl groups. For example, the condensation degree of the siloxane resin may be equal to or more than 95%, preferably equal to or more than 99%.

For example, a resin obtained from non-hydrolytic condensation reaction of an organic alkoxysilane and an organic silanol may have a low condensation degree and a high ratio of hydroxyl groups. Thus, the resin may have a high dielectric constant and dielectric loss tangent and a high water absorption. For example, the resin obtained from non-hydrolytic condensation reaction of an organic alkoxysilane and an organic silanol may have a condensation degree of 80% or less, or 85% or less.

For example, since the siloxane resin obtained from hydrolytic condensation reaction of the mixture of the trialkoxysilane having an alkenyl group, the dialkoxysilane having at least one aryl group and the catalyst may have a reduced dipole moment in whole molecules due to an alkenyl group and an aryl group, decrease of a dielectric constant and a dielectric loss tangent in the siloxane resin may be expected.

For example, since the siloxane resin obtained from hydrolytic condensation reaction of the mixture of the trialkoxysilane having an alkenyl group, the dialkoxysilane having at least one aryl group and the catalyst may have highly linked siloxane bonds, increase of a glass-transition temperature and decrease of a thermal expansion may be expected. Furthermore, since a ratio of loss modulus and storage modulus of the siloxane resin is decreased due to highly linked siloxane bonds, the siloxane resin may not be fluidic at a room temperature. Thus, the siloxane resin composition may form a film without an additional curing process. Therefore, the siloxane resin composition may be advantageous in application of low-dielectric insulation materials for ultra-high frequency/ultra-high speed electronic devices. Furthermore, since the siloxane resin may have increased symmetry due to the dialkoxysilane, additional effects for reducing dielectric constant and dielectric loss tangent may be expected.

For example, since a siloxane resin of obtained from hydrolytic condensation reaction of only dialkoxysilane may have maximized symmetry due to a high ratio of linear siloxane structures, superior effects for reducing dielectric constant and dielectric loss tangent may be expected. However, since the siloxane resin has less linked siloxane bonds, a ratio of loss modulus and storage modulus thereof may be relatively high. Thus, since a siloxane resin composition may not form a film without an additional curing process, the siloxane resin composition may be disadvantageous in application for low-dielectric insulation materials for ultra-high frequency/ultra-high speed electronic devices. Furthermore, since the siloxane resin of obtained from hydrolytic condensation reaction of only dialkoxysilane may cost high, the siloxane resin composition may be disadvantageous in application of low-dielectric insulation materials for ultra-high frequency/ultra-high speed electronic devices.

The siloxane resin or the siloxane resin composition (without a large amount of an additional solvent) may have a ratio of loss modulus and storage modulus, which is 1 or less, which may be solid according to E3277 of American Society for Testing and Materials (ASTM). Thus, such filming ability may be suitable for application of low-dielectric insulation materials for ultra-high frequency/ultra-high speed electronic devices.

Preferably, a mole ratio of the dialkoxysilane having at least one aryl group to the trialkoxysilane having an alkenyl group may be equal to or more than 1. More preferably, the siloxane resin may have the structure of Chemical Formula 1, and a ratio of a and b, which is a mole ratio of the trialkoxysilane having an alkenyl group and the dialkoxysilane having at least one aryl group, may be 1:3 to 1:1. In an embodiment, the number average molecular weight of the compound of the Chemical Formula 1 may be 1,000 g/mol to 15,000 g/mol, and the weight average molecular weight thereof may be 1,000 g/mol to 30,000 g/mol.

The cured material of the siloxane resin composition having the above combination may have a low dielectric constant as well as a low dielectric loss tangent thereby achieving superior insulating performance.

For synthesize the siloxane resin, a reaction condition such as a reaction temperature, a reaction condition, a material, an amount or a concentration of the acid or base aqueous solution may be adjusted in the hydrolytic condensation reaction of the mixture of the trialkoxysilane having an alkenyl group, the dialkoxysilane having at least one aryl group and the catalyst.

The acid aqueous solution as the catalyst may include hydrochloric acid, sulfuric acid, nitric acid, formic acid, acetic acid, toluenesulfonic acid, acetic acid, butyric acid, palmitic acid, oxalic acid, tartaric acid, or a combination thereof.

The base aqueous solution as the catalyst may include an alkali metal compound, an alkaline earth metal compound, a quaternary ammonium compound, ammonia, an aqueous amine compound solution, or a combination thereof.

For example, the base aqueous solution may include an alkali metal compound selected from sodium hydroxide, potassium hydroxide and lithium hydroxide, an alkaline earth metal compound selected from barium hydroxide monohydrate, barium hydroxide octahydrate, calcium hydroxide and magnesium hydroxide, a quaternary ammonium compound selected from tetraalkylammonium silanolate, tetraethylammonium, hydroxide, tetramethylammonium chloride and tetrabutylammonium fluoride, ammonia, an aqueous amine compound solution, or a combination thereof.

Although a concentration of the acid or base aqueous solution may be 0.01N to 10N, embodiments of the present invention are not limited thereto.

For example, when the siloxane resin is synthesized through hydrolytic condensation reaction of the mixture of the trialkoxysilane having an alkenyl group, the dialkoxysilane having at least one aryl group and the catalyst, the mixture of the trialkoxysilane having an alkenyl group, the dialkoxysilane having at least one aryl group and the catalyst may be stirred in an atmosphere of an inert gas at 40° C. to 300° C. and for 2 to 48 hours. A content of the acid or base aqueous solution may be 1 mole to 10 mole when a content of the entire organic silane compounds is 1 mole.

After the siloxane resin is synthesized through the hydrolytic condensation reaction of the mixture of the trialkoxysilane having an alkenyl group, the dialkoxysilane having at least one aryl group and the catalyst, the acid or base aqueous solution may be removed by conventionally known physical or chemical methods to prevent increase of water absorption. For example, after ketone is added to dissolve siloxane resin therein, the ketone with the siloxane resin dissolved therein may be separated from a remainder including the acid or base aqueous solution by solvent extraction method.

The siloxane resin composition may include a radical initiator for polymerization of alkenyl groups of the siloxane resin.

The radical initiator may include at least one selected from the group consisting of 2,3-dimethyl-2,3-diphenylbutane, 2,5-dimethyl-2,5-di(tert-butylperoxy)hexyne-3, 3,6,9-triethyl-3,6,9-trimethyl-1,4,7-triperoxonane, di(tert-butyl)-peroxide, 2,5-dimethyl-2,5-di(tert-butylperoxy)hexane, di(tert-butylperoxy-isopropyl)benzene, tert-butylcumylperoxide, di-(tert-amyl)-peroxide, dicumylperoxide, butyl4,4-di(tert-butylperoxy)valerate, tert-butylperoxybenzoate, 2,2-di(tert-butylperoxy)butane, tert-amylperoxy-benzoate, tert-butylperoxy-acetate, tert-butylperoxy-(2-ethyl hexyl)carbonate, tert-butylperoxy isopropyl carbonate, tert-butylperoxy-3,5,5-trimethyl-hexanoate, 1,1-di(tert-butylperoxy)cyclohexane, tert-amylperoxyacetate, tert-amylperoxy-(2-ethylhexyl)carbonate, 1,1-di (tert-butylperoxy)-3,5,5-trimethylcyclohexane, 1,1-di(tert-amylpooxy)cyclohexane, tert-butyl-monoperoxy-malate, 1,1′-azodi(hexahydrobenzonitrile), tert-butylperoxy-isobutyrate, tert-butyl peroxydiethylacetate, tert-butylperoxy-2-ethyl hexanoate, benzoyl peroxide, tert-amylperoxy-2-ethylhexanoate, di(3-methylbenzoyl)peroxide, 1,1,3,3-tetramethylbutyl peroxy-2-ethylhexanoate, ammonium peroxodisulfate, 2,5-dimethyl-2,5-di(2-ethylhexanoylperoxy hexane, 2,2′-azodi(2-methylbutyronitrile), 2,2′-azodi(isobutyronitrile), didecanoylperoxide, dilauroylperoxide, di(3,5,5-trimethylhexanoyl) peroxide, tert-amylperoxypivalrate, tert-butylperoxyneoheptanoate, 1,1,3,3-tetramethylbutyl peroxypivalate, tert-butylperoxypivalate, dicetylperoxydicarbonate, dimyristyl peroxydicarbonate, di(2-ethylhexyl)peroxydicarbonate, di(4-tert-butylcyclohexyl)peroxycarbonate, diisopropylperoxydicarbonate, tert-butylperoxyneodecanoate, di-sec-butylperoxydicarbonate, tert-amylperoxyneodecanoate, cumyl peroxyneoheptanoate, di(3-methoxybutyl)peroxydicarbonate, 1,1,3,3-tetramethyl butylperoxyneodecanoate, cumylperoxyneodecanoate, diisobutyrylperoxide,bBenzoin, benzoin ethylether, phenylbis(2,4,6-trimethylbenzoyl)phosphine oxide, 1-hydroxycyclohexylphenyl ketone, 2,2-dimethoxy-2-phenylacetophenone, an oxime ester compound and combinations thereof.

A content of the radical initiator may be 0.01 parts to 5 parts by weight based on 100 parts by weight of the siloxane resin.

Initiation of the radical initiator may be performed by heat or photo according to known methods and conditions, however, may not be limited thereto.

The siloxane resin composition may be cured by the radical initiator thereby forming a cured material thereof.

The cured material of the siloxane resin composition may have a dielectric constant of 3.3 or less at a frequency of 10 GHz and a dielectric loss tangent of 0.003 or less at a frequency of 10 GHz, which are suitable for low dielectric insulation materials of ultra-high frequency/ultra-high speed electronic devices.

When the siloxane resin composition is cured after the acid or base catalyst is removed by a physical or chemical method, the cured material may have a water absorption of 0.1% or less, which is suitable for low dielectric insulation materials of ultra-high frequency/ultra-high speed electronic devices.

The cured material may have a glass-transition temperature of 300° C. or more, which is suitable for low dielectric insulation materials of ultra-high frequency/ultra-high speed electronic devices.

The cured material may have a thermal expansion less than 100 ppm/° C. at 20° C. to 300° C., which is suitable for low dielectric insulation materials of ultra-high frequency/ultra-high speed electronic devices.

An embodiment of the present invention may provide a film manufactured by the siloxane resin composition. The film may have a shape of a free-standing film, a sheet or a role.

When a film formed at a high temperature by the siloxane resin composition is cooled to a room temperature, a free-standing film, which can be easily handled, may be obtained due to a low ratio of loss modulus and storage modulus of the siloxane resin composition without an additional curing or half-curing process. In view of manufacturing processes, the above is suitable for low dielectric insulation materials of ultra-high frequency/ultra-high speed electronic devices.

An embodiment of the present invention may provide a composite film or a composite sheet, which includes at least one of a glass cloth and an inorganic filler in addition to the cured material of the siloxane resin composition. The glass cloth or the inorganic filler may be dispersed in the cured material.

The glass cloth may include a woven glass fabric, a non-woven glass fabric, or a mixture thereof, woven with glass fibers including at least one selected from the group consisting of A glass, C glass, D glass, E glass, AR glass, R glass, S glass, S-2 glass, T glass, NE glass, E-CR glass, quartz and combinations thereof,, however, may not be limited thereto.

The inorganic filler may include at least one selected from the group consisting of silica (SiO₂), silsesquioxane, alumina (Al₂O₃), boria (B₂O₃), titania (TiO₂), zirconia (ZrO₂), silicon carbide (SiC), aluminum carbide (Al₄C₃), boron carbide (B₄C), titanium carbide (TiC), zirconium carbide (ZrC), aluminum nitride (AlN), silicon nitride (Si₃N₄), boron nitride (BN), titanium nitride (TiN), zirconium nitride (ZrN) and combinations thereof, however, may not be limited thereto.

The composite film or the composite sheet, which includes at least one of a glass cloth and an inorganic filler in addition to the cured material of the siloxane resin composition, may have a very small thermal expansion, which may be advantageous in a following heating process.

An embodiment of the present invention may provide a copper clad laminate (CCL), which includes a composite film or a composite sheet, which the cured material of the siloxane resin composition.

An embodiment of the present invention may provide a printed circuit board including the copper clad laminate.

An embodiment of the present invention may provide an ultra-high frequency/ultra-high speed electronic device including the printed circuit board.

A siloxane resin composition according to embodiments may achieve a low dielectric constant and dielectric loss tangent, a low water absorption, a high glass-transition temperature, a low thermal expansion, film-forming ability or the like, thereby providing characteristics suitable for low dielectric insulation materials of ultra-high frequency/ultra-high speed electronic devices.

Hereinafter, the present invention will be described in more detail with Examples, but the following Examples are only an exemplary embodiment of the present invention, and the present invention is not limited to the Examples.

### Example 1

Vinyltrimethoxysilane (Gelest, USA) and diphenyldimethoxysilane (Gelest USA) were mixed in a mole ratio of 1:1. Aqueous ammonia solution (NH₄OH(aq), 0.1N) was added thereto, and the mixture was then agitated at 80° C. under a nitrogen atmosphere for 12 hours. In order to remove a base catalyst from a siloxane resin obtained after agitation, the mixture was mixed with methylisobutylketone (MIBK, Samchun Chemical, Korea) and water (H₂O) in a weight ratio of 1:5:4. Due to the difference in solubility, the MIBK layer in which the siloxane resin was dissolved was separated from the water layer in which the base catalyst was dissolved. After obtaining only the MIBK layer, using an under reduced pressure evaporation machine, the MIBK was evaporated to finally obtain the siloxane resin, of which the number average molecular weight was 4,960 g/mol and the weight average molecular weight was 9,280 g/mol.

The degree of condensation (D.O.C) of the siloxane resin calculated using nuclear magnetic resonance spectroscopy and the following formula was about 100%.

$$D . O . C . = \frac{{D}^{1} + 2 {D}^{2} + {T}^{1} + 2 {T}^{2} + 3 {T}^{3}}{2 ( {D}^{0} + {D}^{1} + {D}^{2} ) + 3 ( {T}^{0} + {T}^{1} + {T}^{2} + {T}^{3} )} \times 100$$

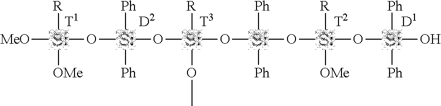

A curable siloxane resin composition was prepared by adding 1 part by weight of di (tert-butyl)-peroxide (DTBP, Sigma Aldrich) based on 100 parts by weight of the siloxane resin.

A cured material was prepared through heat treatment (4 hr, 250° C.) of the prepared siloxane resin composition.

### Example 2

A siloxane resin, a curable siloxane resin composition and a cured material thereof was prepared through a same method as Example 1 except that vinyltrimethoxysilane and diphenyldimethoxysilane were mixed in a mole ratio of 2:3. The number average molecular weight and the weight average molecular weight of the siloxane resin were 2,170 g/mol and the weight average molecular weight was 4,327 g/mol, respectively.

The degree of condensation (D.O.C) of the siloxane resin calculated using nuclear magnetic resonance spectroscopy and the above formula was about 100%.

### Example 3

A siloxane resin, a curable siloxane resin composition and a cured material thereof was prepared through a same method as Example 1 except that vinyltrimethoxysilane and diphenyldimethoxysilane were mixed in a mole ratio of 3:7. The number average molecular weight and the weight average molecular weight of the siloxane resin were 1,608 g/mol and the weight average molecular weight was 3,527 g/mol, respectively.

The degree of condensation (D.O.C) of the siloxane resin calculated using nuclear magnetic resonance spectroscopy and the above formula was about 100%.

### Example 4

A siloxane resin, a curable siloxane resin composition and a cured material thereof was prepared through a same method as Example 1 except for using aqueous hydrochloric acid solution (HCl(aq), 0.1N) instead of the aqueous ammonia solution. The number average molecular weight and the weight average molecular weight of the siloxane resin were 4,130 g/mol and the weight average molecular weight was 8,830 g/mol, respectively.

### Example 5

The curable siloxane resin composition, which was prepared by Example 1, impregnated with a glass cloth (NE-glass, NEA1035, Nittobo) was cured through a same method as Example 1 thereby forming a composite film.

### Example 6

The curable siloxane resin composition, which was prepared by Example 1, with silica (FB, Denka, Japan) added thereto was cured through a same method as Example 1 thereby forming a composite film.

### Comparative Example 1

A siloxane resin, a curable siloxane resin composition and a cured material thereof was prepared through a same method as Example 1 except that vinylmethyldimethoxysilane and diphenyldimethoxysilane were mixed in a mole ratio of 2:3.

### Comparative Example 2

A siloxane resin, a curable siloxane resin composition and a cured material thereof was prepared through a same method as Example 1 except that vinyltriethoxysilane and methyldiethoxysilane were mixed in a mole ratio of 1:1.

### Comparative Example 3

A cured material of a curable siloxane resin composition was prepared through a same method as Example 1 except for omitting removing a catalyst.

### Comparative Example 4

The curable siloxane resin composition, which was prepared by Comparative Example 1, impregnated with glass cloth was cured through a same method as Example 1 thereby forming a composite film.

### Comparative Example 5

The curable siloxane resin composition, which was prepared by Comparative Example 1, with silica added thereto was cured through a same method as Example 1 thereby forming a composite film.

### Experiment 1—Measurement of Dielectric Constant and Dielectric Loss Tangent

The dielectric constant and dielectric loss tangent (Dk/Df) at 10 GHz of the cured siloxane resin compositions and the composited films prepared according to Examples 1 to 6 and Comparative Examples 1 to 5 were measured with a Vector Network analyzer (N5222B, Keysight, USA) and a split post dielectric resonator for 10GHz (QWED, Poland), and the measured results are shown in the following Table 1.

### Experiment 2—Measurement of Water Absorption

The water absorptions of the cured siloxane resin compositions and the composited films prepared according to Examples 1 to 6 and Comparative Examples 1 to 5 were measured according to ASTM D570, and the measured results are shown in the following Table 1.

### Experiment 3—Measurement of Glass-Transition Temperature

The glass-transition temperatures of the cured siloxane resin compositions and the composited films prepared according to Examples 1 to 6 and Comparative Examples 1 to 5 were measured with Thermo Mechanical Analyzer (TMA, SS6100, SII Co., Japan) according to ASTM E1545, and the measured results are shown in the following Table 1.

### Experiment 4—Measurement of Thermal Expansion

The glass-transition temperatures of the cured siloxane resin compositions and the composited films prepared according to Examples 1 to 6 and Comparative Examples 1 to 5 were measured with Thermo Mechanical Analyzer (TMA, SS6100, SII Co., Japan) according to ASTM E831, and the measured results are shown in the following Table 1.

### Experiment 5—Measurement of Ratio of Loss Modulus And Storage Modulus

The ratios (tand) of the loss modulus and the storage modulus of the siloxane resin compositions according to Examples 1 to 6 and Comparative Examples 1 to 5 were measured with a rheometer (MCR302, Anton Paar, Austria) according to ASTM E277, and the measured results are shown in the following Table 1.

TABLE 1

| | | | | Glass-transition | Thermal | |
|---|---|---|---|---|---|---|
| | | | Water | temperature | expansion | |
| | Dk | Df | absorption | (° C.) | (ppm/° C.) | tand |
| Example 1 | 3.03 | 0.0028 | 0.05% | >300 | 71 | 0.71 |
| Example 2 | 3.01 | 0.0026 | 0.06% | >300 | 73 | 0.75 |
| Example 3 | 3.01 | 0.0018 | 0.08% | >300 | 82 | 0.85 |
| Example 4 | 2.98 | 0.0029 | 0.06% | >300 | 72 | 0.73 |
| Example 5 | 3.23 | 0.0024 | 0.08% | >300 | 10 | 0.82 |
| Example 6 | 3.21 | 0.0022 | 0.09% | >300 | 46 | 0.78 |
| Comparative | 2.94 | 0.002 | 0.05% | >300 | 83 | 80 |
| Example 1 | | | | | | |
| Comparative | 3.00 | 0.0035 | 0.06% | >300 | 98 | 101 |
| Example 2 | | | | | | |
| Comparative | 3.00 | 0.0018 | 0.5% | >300 | 80 | 0.83 |
| Example 3 | | | | | | |
| Comparative | 3.18 | 0.0024 | 0.06% | >300 | 11 | 78 |
| Example 4 | | | | | | |
| Comparative | 3.17 | 0.0021 | 0.06% | >300 | 41 | 76 |
| Example 5 | | | | | | |

Referring to Table 1, the cured siloxane resin compositions and the composited films prepared according to Examples 1 to 6 had the dielectric constant of 3.3 or less and the dielectric loss tangent of 0.003 or less at 10 GHz. Thus, it can be confirmed that they have suitable dielectric characteristics for low dielectric insulation materials of ultra-high frequency/ultra-high speed electronic devices.

Referring to Table 1, the cured siloxane resin compositions and the composited films prepared according to Examples 1 to 6 had the water absorption of 0.1% or less. Thus, it can be confirmed that they have suitable water absorption characteristics for low dielectric insulation materials of ultra-high frequency/ultra-high speed electronic devices.

Referring to Table 1, the cured siloxane resin compositions and the composited films prepared according to Examples 1 to 6 did not show glass-transition at 300° C. or less, which means that the cured siloxane resin compositions and the composited films had the glass-transition temperature equal to or more than 300° C. Thus, it can be confirmed that they have suitable thermal characteristics for low dielectric insulation materials of ultra-high frequency/ultra-high speed electronic devices.

Referring to Table 1, the cured siloxane resin compositions and the composited films prepared according to Examples 1 to 6 had the thermal expansion less than 100 ppm/° C. Thus, it can be confirmed that they have suitable thermal expansion characteristics for low dielectric insulation materials of ultra-high frequency/ultra-high speed electronic devices.

In contrast, referring to Table 1, the cured siloxane resin composition prepared according to Comparative Example 2 had the dielectric loss tangent more than 0.003 at 10 GHz, which is not suitable for low dielectric insulation materials of ultra-high frequency/ultra-high speed electronic devices.

Referring to Table 1, the cured siloxane resin composition prepared according to Comparative Example 3 had the water absorption more than 0.1%, which is not suitable for low dielectric insulation materials of ultra-high frequency/ultra-high speed electronic devices.

Referring to Table 1, the cured siloxane resin compositions and the composited films prepared according to Comparative Examples 1 to 5 had ‘tand’ more than 1, which means fluidity at a room temperature. Thus, they cannot form a film before a curing process, which is not suitable for low dielectric insulation materials of ultra-high frequency/ultra-high speed electronic devices.

Referring to Table 1, although showing some suitable characteristics, the cured siloxane resin compositions and the composited films prepared according to Comparative Examples 1 to 5 are not wholly suitable for low dielectric insulation materials of ultra-high frequency/ultra-high speed electronic devices.

Although preferred embodiments of the present invention have been described in detail above, the scope of the present invention is not limited thereto, and various modifications and improvements by a person of an ordinary skill in the art using the basic concept of the present invention as defined in the following claim ranges also fall within the scope of the present invention.

1. A curable siloxane resin composition comprising:
a siloxane resin and a radical initiator,
the siloxane resin obtained through a hydrolytic condensation reaction of a mixture of a trialkoxysilane having an alkenyl group and a dialkoxysilane having at least one aryl group, the siloxane resin being represented by the following Chemical Formula 1, 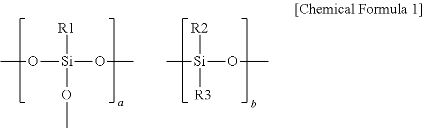
in Chemical Formula 1, R1 includes a linear or branched C₂₋₂₀ alkenyl group, R2 includes a linear or branched C₆₋₂₀ aryl group, R3 includes a linear or branched C₆₋₂₀ aryl group, a C₁₋₂₀ alkyl group or a C₂₋₂₀ alkenyl group, a and b are natural numbers, and b is larger than or equal to a.

2. The curable siloxane resin composition of claim 1, wherein the number average molecular weight of the siloxane resin is 1,000 g/mol to 15,000 g/mol, and the weight average molecular weight of the siloxane resin is 1,000 g/mol to 30,000 g/mol.

3. The curable siloxane resin composition of claim 1, wherein the trialkoxysilane includes at least one of the group consisting of vinyltrimethoxysilane, vinyltriethoxysilane, allyltrimethoxysilane, allyltriethoxysilane, trimethoxy(4-vinylphenyl)silane and triethoxy(4-vinylphenyl)silane.

4. The curable siloxane resin composition of claim 1, wherein the dialkoxysilane includes at least one of the groups consisting of methylphenyldimethoxysilane, methylphenyldiethoxysilane, diphenyldimethoxysilane, diphenyldiethoxysilane, 1,4-bis(methoxydimethylsilyl)benzene, 1,4-bis(ethoxydimethylsilyl)benzene, 4-vinyldiphenyldimethoxysilane and 4-vinyldiphenyldiethoxysilane.

5. The curable siloxane resin composition of claim 1, wherein the radical initiator includes at least one of the group consisting of 2,3-dimethyl-2,3-diphenylbutane, 2,5-dimethyl-2,5-di(tert-butylperoxy)hexyne-3, 3,6,9-triethyl-3,6,9-trimethyl-1,4,7-triperoxonane, di(tert-butyl)-peroxide, 2,5-dimethyl-2,5-di(tert-butylperoxy) hexane, di(tert-butylperoxy-isopropyl)benzene, tert-butylcumylperoxide, di-(tert-amyl)-peroxide, dicumylperoxide, butyl4,4-di(tert-butylperoxy)valerate, tert-butylperoxybenzoate, 2,2-di(tert-butylperoxy)butane, tert-amylperoxy-benzoate, tert-butylperoxy-acetate, tert-butylperoxy-(2-ethyl hexyl)carbonate, tert-butylperoxy isopropyl carbonate, tert-butylperoxy-3,5,5-trimethyl-hexanoate, 1, 1-di(tert-butylperoxy)cyclohexane, tert-amylperoxyacetate, tert-amylperoxy-(2-ethylhexyl) carbonate, 1,1-di(tert-butylperoxy)-3,5,5-trimethylcyclohexane, 1,1-di(tert-amylpooxy)cyclohexane, tert-butyl-monoperoxy-malate, 1,1′-azodi(hexahydrobenzonitrile), tert-butylperoxy-isobutyrate, tert-butyl peroxydiethylacetate, tert-butylperoxy-2-ethyl hexanoate, benzoyl peroxide, tert-amylperoxy-2-ethylhexanoate, di(3-methylbenzoyl)peroxide, 1,1,3,3-tetramethylbutyl peroxy-2-ethylhexanoate, ammonium peroxodisulfate, 2,5-dimethyl-2,5-di(2-ethylhexanoylperoxy)hexane, 2,2′-azodi(2-methylbutyronitrile), 2,2′-azodi(isobutyronitrile), didecanoylperoxide, dilauroylperoxide, di(3,5,5-trimethylhexanoyl)peroxide, tert-amylperoxypivalrate, tert-butylperoxyneoheptanoate, 1,1,3,3-tetramethylbutyl peroxypivalate, tert-butylperoxypivalate, dicetylperoxydicarbonate, dimyristyl peroxydicarbonate, di(2-ethylhexyl)peroxydicarbonate, di(4-tert-butylcyclohexyl)peroxycarbonate, diisopropylperoxydicarbonate, tert-butylperoxyneodecanoate, di-sec-butylperoxydicarbonate, tert-amylperoxyneodecanoate, cumyl peroxyneoheptanoate, di(3-methoxybutyl)peroxydicarbonate, 1,1,3,3-tetramethyl butylperoxyneodecanoate, cumylperoxyneodecanoate, diisobutyrylperoxide,bBenzoin, benzoin ethylether, phenylbis(2,4,6-trimethylbenzoyl)phosphine oxide, 1-hydroxycyclohexylphenyl ketone, 2,2-dimethoxy-2-phenylacetophenone, and an oxime ester compound.

6. The curable siloxane resin composition of claim 1, wherein a ratio of loss modulus and storage modulus of the curable siloxane resin composition is 1 or less.

7. A film including a cured material of the curable siloxane resin composition of claim 1.

8. The film of claim 7, wherein the cured material has a dielectric constant of 3.3 or less and a dielectric loss tangent of 0.003 or less at a frequency of 10 GHz.

9. A composite film including a cured material of the curable siloxane resin composition of claim 1 and at least one of a glass cloth and an inorganic filler.

10. A copper clad laminate including the composite film of claim 9.
